(19) United States
(12) Patent Application Publication
(10) Pub. No.: US 2025/0006745 A1
(43) Pub. Date: Jan. 2, 2025

(54) ARRAY SUBSTRATE AND DISPLAY PANEL

(71) Applicant: Hubei Yangtze Industrial Innovation Center of Advanced Display Co., LTD., Wuhan (CN)

(72) Inventors: Xin CHEN, Wuhan (CN); Jiaxian LIU, Wuhan (CN)

(21) Appl. No.: 18/601,053

(22) Filed: Mar. 11, 2024

(30) Foreign Application Priority Data
Jun. 28, 2023 (CN) 202310786823.0

(51) Int. Cl. H01L 27/12; G09G 3/3225

(52) U.S. Cl. CPC H01L 27/1222; G09G 3/3225; G09G 2300/0842; H01L 27/1248

(57) ABSTRACT

An array substrate includes a substrate, a semiconductor layer over the substrate, a gate over a side of the semiconductor layer away from the substrate, and a source and a drain on sides of the gate. The semiconductor layer includes a channel region, a first doping region, and a first ohmic contact region, which are sequentially connected. A shielding layer is between the substrate and the semiconductor layer. The shielding layer is connected to a fixed potential, and the shielding layer at least partially overlaps with the first doping region in a direction perpendicular to a plane of the substrate.

### CROSS-REFERENCES TO RELATED APPLICATION

This application claims the priority of Chinese Patent Application No. 202310786823.0, filed on Jun. 28, 2023, the content of which is incorporated by reference in its entirety.

### TECHNICAL FIELD

The present disclosure generally relates to the field of display technologies and, more particularly, relates to an array substrate and a display panel.

### BACKGROUND

Display panels serve as a crucial component of display devices for realizing desirable display functions. Presently, display screens mainly include Liquid Crystal Display (LCD) panels, Organic Light-Emitting Diode (OLED) panels, Micro Light-Emitting Diode (Micro LED) panels, and Mini Light-Emitting Diode (Mini LED) panels.

Thin Film Transistors (TFTs) serve as the key driving components in LCD display panels, LED display panels, Micro LED panels, and Mini LED panels. The transistor may include a gate, a source, a drain, and an active layer. The source and drain are connected to the active layer. When a voltage is applied to the gate, the surface of the active layer transforms from a depletion layer to an electron accumulation layer as the gate voltage increases, forming an inversion layer. Upon reaching a strong inversion state (i.e., the turn-on voltage), charge carriers in the active layer move to facilitate conduction between the source and the drain. However, TFTs in related technologies suffer from the short-channel effect, leading to a decline in the electrical performance of the array substrate.

Therefore, there is an urgent need to provide an array substrate and a display panel to mitigate the short-channel effect.

### SUMMARY

One embodiment of the present disclosure provides an array substrate. The array substrate includes a substrate, a semiconductor layer over the substrate, a gate over a side of the semiconductor layer away from the substrate, and a source and a drain on sides of the gate. The semiconductor layer includes a channel region, a first doping region, and a first ohmic contact region, which are sequentially connected. A shielding layer is between the substrate and the semiconductor layer. The shielding layer is connected to a fixed potential, and the shielding layer at least partially overlaps with the first doping region in a direction perpendicular to a plane of the substrate.

Another embodiment of the present disclosure provides a display panel, including an array substrate. The array substrate includes a substrate, a semiconductor layer over the substrate, a gate over a side of the semiconductor layer away from the substrate, and a source and a drain on sides of the gate. The semiconductor layer includes a channel region, a first doping region, and a first ohmic contact region, which are sequentially connected. A shielding layer is between the substrate and the semiconductor layer. The shielding layer is connected to a fixed potential, and the shielding layer at least partially overlaps with the first doping region in a direction perpendicular to a plane of the substrate.

### BRIEF DESCRIPTION OF THE DRAWINGS

The attached figures, incorporated into this disclosure as part of the specification, illustrate embodiments of the present disclosure and are used in conjunction with their descriptions to elucidate the principles of the present disclosure.

FIG. 1 illustrates a planar structural schematic diagram of an exemplary array substrate according to various embodiments of the present disclosure.

FIG. 2 illustrates a partial magnified view of region M in FIG. 1.

FIG. 3 is a cross-sectional view along the A-A′ direction in FIG. 2.

FIG. 4 illustrates a charge carrier path in a semiconductor without the arrangement of a first doping region and a shielding layer.

FIG. 5 illustrates a charge carrier path according to various embodiments of the present disclosure.

FIG. 6 illustrates a planar structural schematic diagram of another exemplary array substrate according to various embodiments of the present disclosure.

FIG. 7 illustrates a partial magnified view of region N in FIG. 6.

FIG. 8 is a cross-sectional view along the B-B′ direction in FIG. 7.

FIG. 9 illustrates a planar structural schematic diagram of another exemplary array substrate according to various embodiments of the present disclosure.

FIG. 10 illustrates a partial magnified view of region O in FIG. 9.

FIG. 11 illustrates a cross-sectional view along the C-C′ direction in FIG. 10.

FIG. 12 illustrates a planar structural schematic diagram of another exemplary array substrate according to various embodiments of the present disclosure.

FIG. 13 illustrates a planar structural schematic diagram of another exemplary array substrate according to various embodiments of the present disclosure.

FIG. 14 illustrates a partial magnified view of region P in FIG. 12.

FIG. 15 illustrates a cross-sectional view along the D-D′ direction in FIG. 14.

FIG. 16 illustrates a planar structural schematic diagram of another exemplary array substrate according to various embodiments of the present disclosure.

FIG. 17 illustrates a cross-sectional view along the E-E′ direction in FIG. 16.

FIG. 18 illustrates a planar structural schematic diagram of another exemplary array substrate according to various embodiments of the present disclosure.

FIG. 19 illustrates a pixel circuit diagram according to various embodiments of the present disclosure.

FIG. 20 illustrates a cross-sectional view along the F-F′ direction in FIG. 18.

FIG. 21 illustrates a planar structural schematic diagram of another exemplary array substrate according to various embodiments of the present disclosure.

FIG. 22 illustrates a cross-sectional view along the G-G′ direction in FIG. 21.

FIG. 23 illustrates a planar structural schematic diagram of another exemplary array substrate according to various embodiments of the present disclosure.

FIG. 24 illustrates a cross-sectional view along the H-H′ direction in FIG. 23.

FIG. 25 illustrates a cross-sectional view along the F-F′ direction in FIG. 18.

FIG. 26 illustrates a planar structural schematic diagram of an exemplary display panel according to various embodiments of the present disclosure.

### DETAILED DESCRIPTION

Various exemplary embodiments of the present disclosure will be described in detail with reference to the accompanying drawings. It should be noted that, unless otherwise specifically stated, the relative arrangement, numerical expressions, and values of the components and steps described in these embodiments do not limit the scope of the present disclosure.

The description of at least one exemplary embodiment provided below is actually illustrative and by no means limits the scope of the present disclosure and its applications or uses.

Technologies, methods, and devices known to those skilled in the relevant art may not be discussed in detail, but, when necessary, such technologies, methods, and devices should be considered as part of the specification.

In all examples shown and discussed here, any specific values should be interpreted as illustrative only and not as limitations. Therefore, other examples of exemplary embodiments may have different values.

It should be noted that similar reference numerals and letters in the following drawings represent similar items, and once an item is defined in one drawing, it does not need to be further discussed in subsequent drawings.

The present disclosure provides an array substrate and a display panel for mitigating the short-channel effect of transistors in the array substrate.

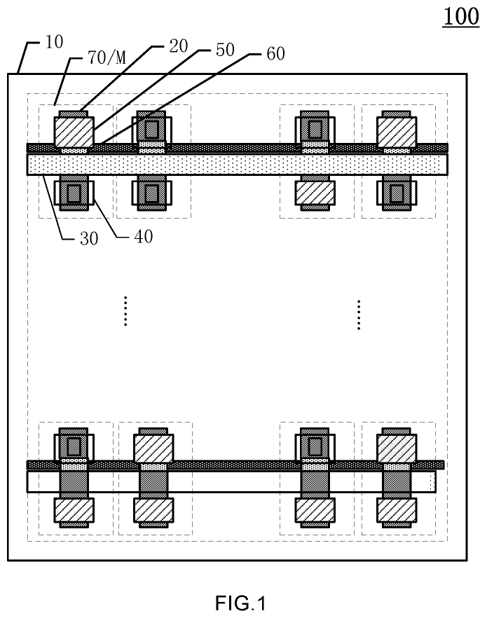

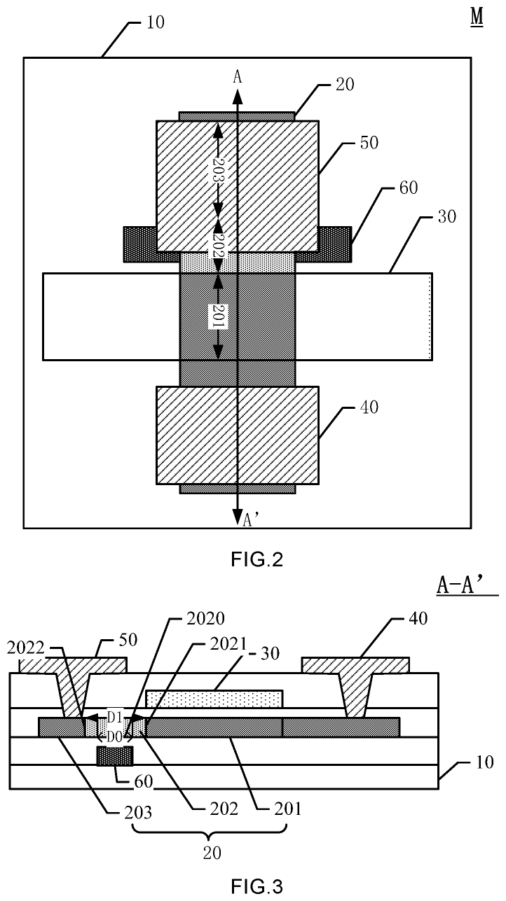

FIG. 1 illustrates a planar structural schematic diagram of an exemplary array substrate according to various embodiments of the present disclosure, FIG. 2 illustrates a partial magnified view of region M in FIG. 1, and FIG. 3 illustrates a sectional view along the A-A′ direction in FIG. 2. As shown in FIGS. 1-3, an array substrate 100 includes a substrate 10, a plurality of semiconductor layers 20 over one side of the substrate 10, a plurality of gates 30 over the side of the semiconductor layer 20 away from the substrate 10, and a plurality of sources 40 and a plurality of drains 50 over the side of the gates 30 away from the substrate 10. The semiconductor layer 20 includes a channel region 201, a first doping region 202, and a first ohmic contact region 203 sequentially connected with the first doping region 202 and the first ohmic contact region 203. A plurality of shielding layers 60 connected to fixed potentials are between the substrate 10 and the plurality of semiconductor layers 20. In the direction perpendicular to the plane of the substrate 10, the plurality of shielding layers 60 overlap at least partially with the plurality of first doping regions 202.

For example, the substrate 10 may be a flexible substrate or a rigid substrate. The flexible substrate may be made of any suitable flexible insulating material. For example, the flexible substrate may be made of polymer materials such as polyimide, polycarbonate, polysulfone, polyethylene terephthalate, polyethylene naphthalate, polyaryl compounds, and/or glass fiber-reinforced plastics. The flexible substrate may be transparent, semi-transparent, or opaque. The flexible substrate may also be a rigid substrate. For example, the substrate may be made of glass. The present disclosure is not limited thereto.

In some embodiments, one or more transistors are provided over the substrate 10. A transistor may include the semiconductor layer 20, the gate 30, the source 40, and the drain 50. The number of transistors in FIG. 1 is for illustrative purposes only and does not limit the number of transistors in an actual product. Optionally, a pixel circuit 70 in the array substrate 100 may include one or more transistors. For example, a 1T1C pixel circuit includes one transistor and one storage capacitor, a 7T1C pixel circuit includes seven transistors and one storage capacitor, and an 8T1C pixel circuit includes eight transistors and one storage capacitor. For illustrative purposes, FIG. 1 only shows one pixel circuit 70 having one transistor as an example.

The plurality of semiconductor layers 20 are over one side of the substrate 10 and the material may include silicon. The semiconductor layer 20 according to various embodiments of the present disclosure may be a P-type semiconductor or an N-type semiconductor. The P-type semiconductor may be formed by doping a small amount of trivalent elements materials, such as boron, into pure silicon, forming holes, i.e., vacancies lacking electrons. These holes can be filled by electrons from donor impurities, forming positive charges. Therefore, the current in the P-type semiconductor is mainly carried by holes. The N-type semiconductor may be formed by doping a small amount of pentavalent elements materials, such as phosphorus, into pure silicon, forming free electrons. These free electrons can move freely in the semiconductor layer 20, forming negative charges. Therefore, the current in the N-type semiconductor is mainly carried by free electrons. In FIGS. 1, 2, and 3, different patterns are used in the first doping region 202 and the channel region 201 to indicate differences.

The semiconductor layer 20 includes a channel region 201, a first doping region 202, and a first ohmic contact region 203. The channel region 201 may overlap with the gate 30. The first doping region 202 and the first ohmic contact region 203 may not overlap with the gate 30. The first ohmic contact region 203 is electrically connected to the source 40 or the drain 50.

The material of the gate 30 over the side of the semiconductor layer 20 away from the substrate 10 may include molybdenum. The material of the source 40 and the drain 50 over the side of the gate 30 away from the substrate 10 may include metals or alloys such as aluminum, chromium, titanium or a combination thereof.

The material of the shielding layer 60 may be metal, which has both conductivity and light-blocking characteristics. For example, the material of the shielding layer 60 may be the same material of the gate 30, including molybdenum. The material of the shielding layer 60 may also be the same material of the source 40 and the drain 50, including metals or alloys, such as aluminum, chromium, titanium or a combination thereof. The present disclosure is not limited thereto.

In some embodiments, the array substrate 100 may further include a plurality of buffer layers (not shown in the figure), and the plurality of buffer layers are between the plurality of shielding layers 60 and the plurality of semiconductor layers 20. This may increase the distance between the shielding layer 60 and the gate 30 to prevent coupling interference between the potential of the shielding layer 60 and the potential of the gate 30.

The plurality of shielding layers 60 are connected to fixed potentials. Optionally, the plurality of shielding layers 60 of multiple transistors may be connected as a whole to a same fixed potential, as shown in FIG. 1. The plurality of shielding layers 60 of multiple transistors may also be not connected as a whole and thus connected to different fixed potentials. It should be noted that the fixed potential refers to a potential that is fixed within a certain time interval and does not mean that the connected potential is constant. For example, the display panel of the array substrate 100 includes a first-time phase and a second-time phase during display. The first-time phase is the data refresh phase of the pixel circuit, and the second-time phase is the data holding phase. The first-time phase corresponds to a high-brightness display, while the second time phase corresponds to a low-brightness display. During the first-time phase, a first fixed potential V1 is connected, and during the second time phase, a second fixed potential V2 is connected. Optionally, the fixed potentials connected during the first-time phrase and the second-time phase may be unequal, i.e., V1/V2. In some embodiments, different transistors may be connected to unequal fixed potentials.

The shielding layer 60 may overlap partially with the first doping region 202 in the direction perpendicular to the plane of the substrate 10. Optionally, the first doping region 202 and the shielding layer 60 may have overlapping projections in the plane of the substrate 10, or the projection of the first doping region 202 in the plane of the substrate 10 may be within the projection of the shielding layer 60 in the plane of the substrate 10. Specific details in the present disclosure are not limited thereto. FIGS. 1 to 3 are merely illustrative examples of the partial overlap between the projection of the first doping region 202 in the plane of the substrate 10 and the projection of the shielding layer 60 in the plane of the substrate 10.

It is noted that the first ohmic contact region 203 may be connected to the source 40 or to the drain 50. That is, the first doping region 202 may be over the side of the channel region 201 near the source 40 or over the side near the drain 50.

Generally, in order to reduce a size of transistors, a length of the conductive channel may be reduced. If the length of the conductive channel is reduced to the level of tens of nanometers or even a few nanometers, a short-channel effect may occur. The short-channel effect mainly includes a decrease in threshold voltage with decreasing channel length (threshold voltage drift), a decrease in the barrier caused by leakage (kink effect), and thermal electron effect. For semiconductor devices with long channels, the channel may be equivalent to resistance. When the gate voltage is within a certain range, the semiconductor may exhibit normal semiconductor characteristics with the source-drain input voltage, and the input current may be constant. However, for short channels, as the voltage increases, the threshold voltage drift may become more severe, and the depletion layer between the drain and the source may become closer, causing the current in the channel to flow from the drain to the source. This may reduce the height of the barrier at the source, increase the current in the drain 50, and cause a drain induced barrier lowering (DIBL) effect. Additionally, at high drain voltage, avalanche multiplication of charge carriers may occur near the drain, causing the current in the drain to increase rapidly with drain voltage, leading to the kink effect. Furthermore, with increasing voltage, thermal effect may occur, generating impact-induced electrons and causing sudden changes in current.

The array substrate 100 of the present disclosure may include a substrate 10, a plurality of semiconductor layers 20 over one side of the substrate 10, a plurality of gates 30 over the side of the semiconductor layers 20 away from the substrate 10, a plurality of sources 40 and a plurality of drains 50 over the side of the gates 30 away from the substrate 10. The semiconductor layer 20 may include a channel region 201, a first doping region 202, and a first ohmic contact region 203 sequentially connected with the channel region 201 and the first doping region 202. A plurality of shielding layers 60 connected to a plurality of fixed potentials are provided between the substrate 10 and the plurality of semiconductor layers 20. In the direction perpendicular to the plane of the substrate 10, the shielding layer 60 overlaps at least partially with the first doping region 202. Low concentration doping is performed in the first doping region 202. When a voltage is applied to the transistor and current flows between the channel region 201 and the first ohmic contact region 203, the lower doping concentration in the first doping region 202 may reduce the number of charge carriers. This may solve the avalanche multiplication issue of charge carriers in the first doping region 202. In this present disclosure, a projection of the shielding layer 60 in the plane of the substrate 10 overlaps at least partially with a projection of the first doping region 202 in the plane of the substrate 10. This may form a capacitive coupling structure between the shielding layer 60 and the first doping region 202. When the shielding layer 60 is connected to a fixed potential, the electric field intensity in the region where the shielding layer 60 overlaps with the first doping region 202 in the direction perpendicular to the plane of the substrate 10 may be lowered according to the principle of capacitive coupling. This may prevent avalanche multiplication of charge carriers, reduce thermal effect, prevent sudden changes in current and mitigate the kink effect, thus addressing the short-channel effect issue.

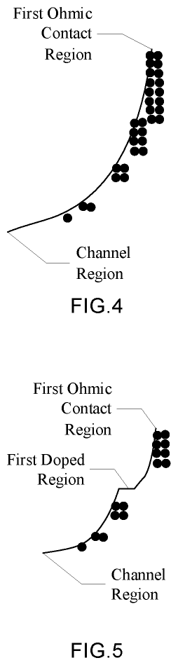

In some embodiments, referring to FIGS. 1 to 3, as well as FIGS. 4 and 5, FIG. 4 illustrates a charge carrier path in a semiconductor of the related art without the arrangement of the first doping region and the shielding layer. FIG. 5 illustrates a charge carrier path according to various embodiments of the present disclosure. In this embodiment, the first ohmic contact region 203 is electrically connected to the drain 50.

In this embodiment, the first ohmic contact region 203 is electrically connected to the drain 50, and the first doping region 202 with a lower doping concentration is over the side of the drain 50. Referring to FIGS. 4 and 5, FIGS. 4 and 5 illustrate paths of charge carriers. As shown in FIG. 4, without the first doping region and the shielding layer, the numbers of the charge carriers may increase gradually in the direction from the channel region to the first ohmic contact region, leading to avalanche multiplication of charge carriers at the area of the first ohmic contact region. Referring to FIG. 5, in the direction from the channel region 201 to the first ohmic contact region 203, the first doping region 202 in the present disclosure may act as a barrier. The low doping concentration in the first doping region 202 increases the resistance. This may prevent the avalanche multiplication of charge carriers to some extent, reduce thermal effect, prevent sudden changes in current, and mitigate the kink effect and the short-channel effect.

It should be noted that, after applying a voltage to the source 40 and the drain 50 of the transistor, fewer charge carriers may be present over the side of the source 40, while more charge carriers may be present over the side of the drain 50. Therefore, in this embodiment, an arrangement of the first doping region 202 over the side of the drain 50 may prevent the avalanche multiplication of charge carriers effectively.

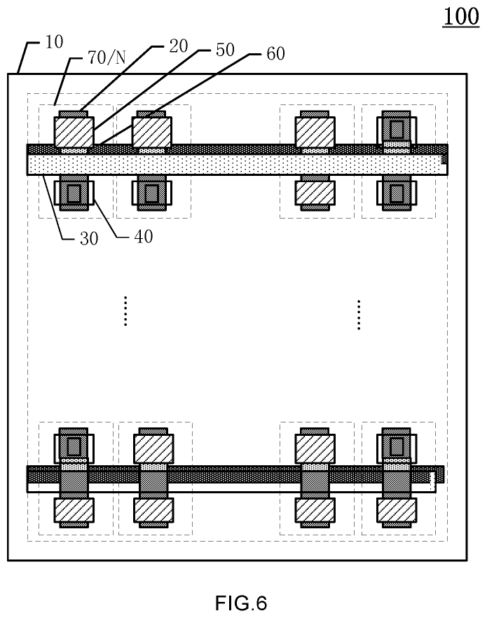

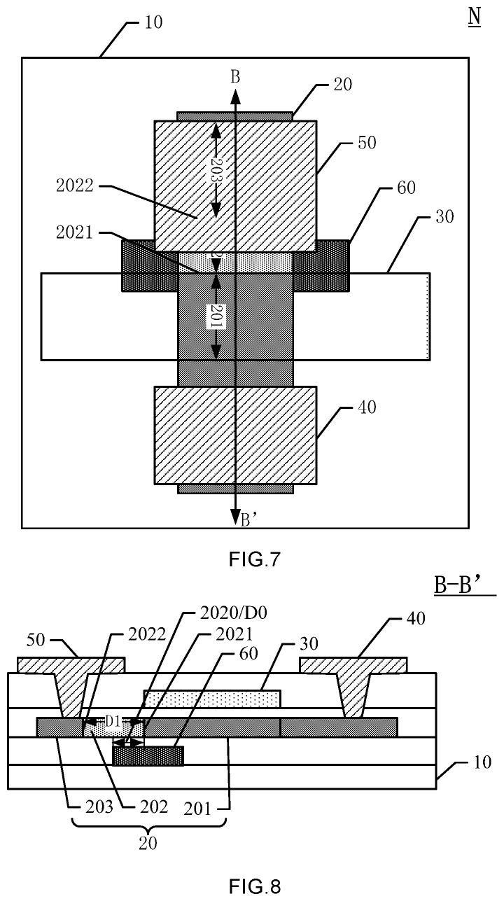

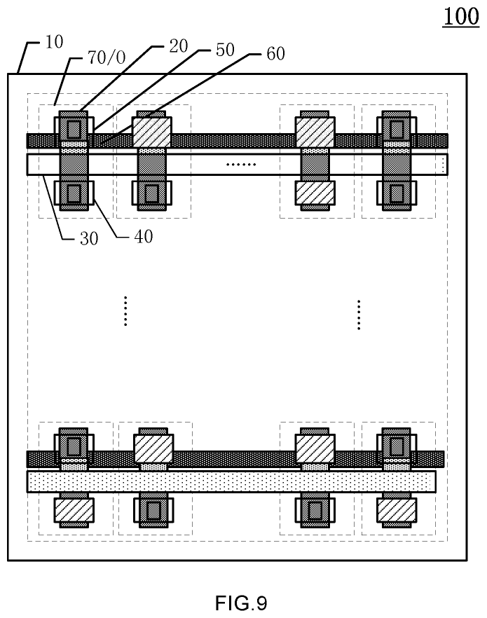

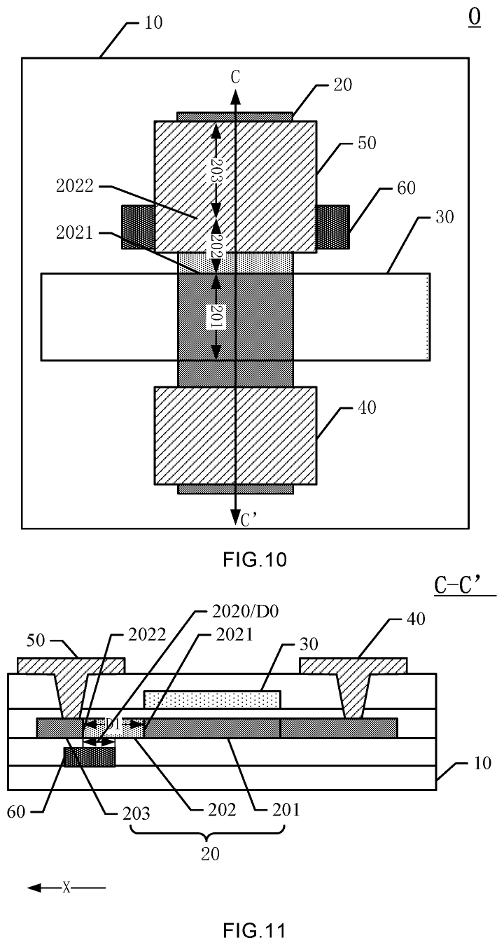

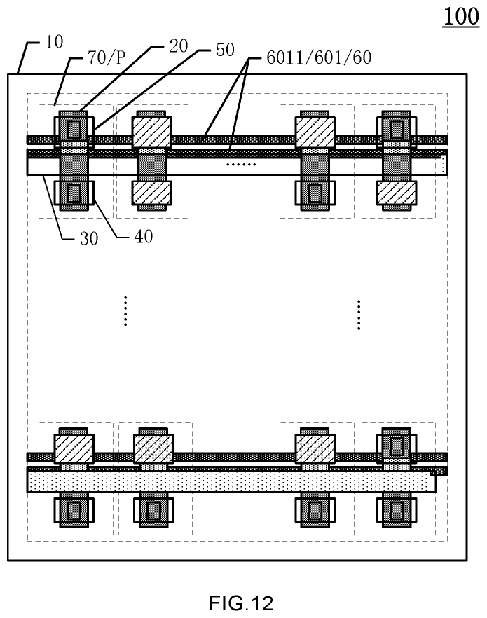

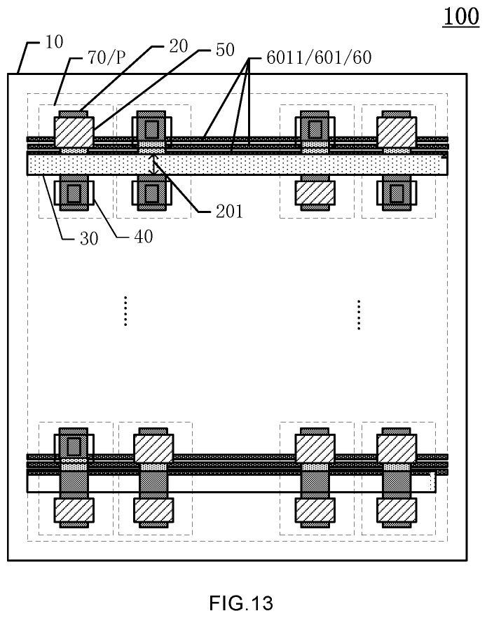

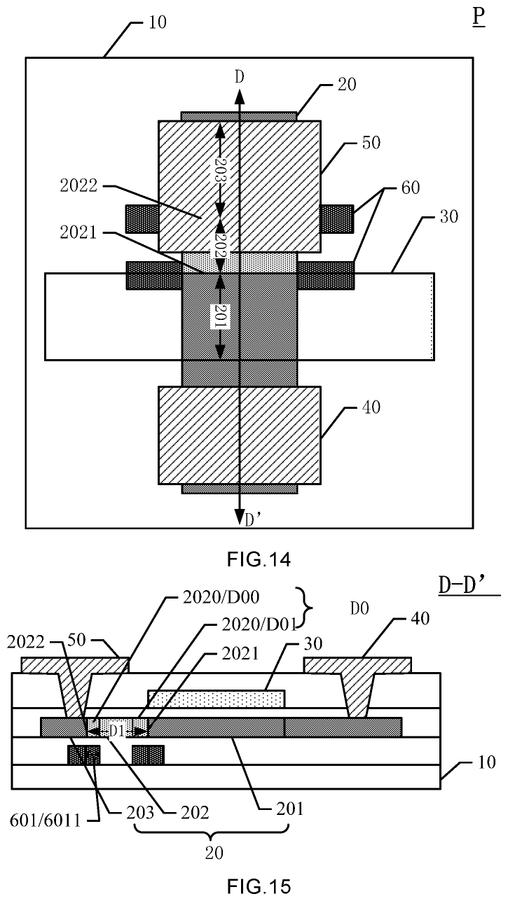

In some embodiments, referring to FIGS. 6-15, FIG. 6 illustrates a planar structural schematic diagram of another exemplary array substrate according to various embodiments of the present disclosure. FIG. 7 illustrates a partial magnified view of region N in FIG. 6. FIG. 8 illustrates a cross-sectional view along the B-B′ direction in FIG. 7. FIG. 9 illustrates a planar structural schematic diagram of another exemplary array substrate according to various embodiments of the present disclosure. FIG. 10 illustrates a partial magnified view of region O in FIG. 9. FIG. 11 illustrates a cross-sectional view along the C-C′ direction in FIG. 10. FIG. 12 illustrates a planar structural schematic diagram of another exemplary array substrate according to various embodiments of the present disclosure. FIG. 13 illustrates a planar structural schematic diagram of another exemplary array substrate according to various embodiments of the present disclosure. FIG. 14 illustrates a partial magnified view of region P in FIG. 12. FIG. 15 illustrates a cross-sectional view along the D-D′ direction in FIG. 14. A first junction 2021 is the junction between the first doping region 202 and the channel region 201. A second junction 2022 is the junction between the first doping region 202 and the first ohmic contact region 203. In the direction perpendicular to the plane of the substrate 10, the shielding layer 60 may cover the first junction 2021 and/or the second junction 2022.

As shown in FIGS. 6 to 8, the shielding layer 60 covers the first junction 2021 in the direction perpendicular to the plane of the substrate 10. As shown in FIGS. 9 to 11, the shielding layer 60 covers the second junction 2022 in the direction perpendicular to the plane of the substrate 10. As shown in FIGS. 12 to 15, the shielding layer 60 covers both the first junction 2021 and the second junction 2022 in the direction perpendicular to the plane of the substrate 10. For example, the shielding layer 60 includes two sub-portions 6011 and the two sub-portions 6011 cover the first junction 2021 and the second junction 2022 respectively, as shown in FIG. 12. For example, the shielding layer 60 includes three sub-portions 6011 and two of the sub-portions 6011 cover the first junction 2021 and the second junction 2022 respectively, as shown in FIG. 13. In some embodiments, the shielding layer 60 may be one portion, covering both the first junction 2021 and the second junction 2022, which is not shown in the figures.

The shielding layer 60 may cover the first junction 2021 between the first doping region 202 and the channel region 201, the second junction 2022 between the first doping region 202 and the first ohmic contact region 203, and/or both the first junction 2021 and the second junction 2022. It is understood that the transmission resistance of the first doping region 202 is high with the low doping concentration of the first doping region 202. The doping concentrations in the channel region 201 and the first ohmic contact region 203 may be different from the doping concentration of the first doping region 202. Therefore, the accumulation of charge carriers may occur at the area of the first junction 2021 and/or the second junction 2022. In the direction perpendicular to the plane of the substrate 10, the shielding layer 60 covers the first junction 2021 and/or the second junction 2022. When the shielding layer 60 is connected to the fixed potential, it may stabilize the electric field intensity of the first junction 2021 and/or the second junction 2022 effectively according to the principle of capacitive coupling. This may prevent avalanche multiplication of charge carriers at the first junction 2021 and/or the second junction 2022, prevent sudden changes in current at the first junction 2021 and/or the second junction 2022, and mitigate the kink effect effectively, i.e., mitigate the short-channel effect.

In some embodiments, referring to FIG. 3, FIG. 8, FIG. 11, and FIG. 15, the first doping region 202 includes a first region 2020. The first region 2020 is an area overlapping with the shielding layer 60 in the direction perpendicular to the plane of the substrate 10. A first direction is the direction from the channel region 201 to the first ohmic contact region 203. Along the first direction, a total width of the first region 2020 is D0, and a total width of the first doping region 202 is D1, where D0=½D1.

The first region 2020 is an area in the first doping region 202 overlapping with the shielding layer 60 in the direction perpendicular to the plane of the substrate 10 is. As shown in FIG. 3, one first region 2020 is between the first junction and the second junction. As shown in FIG. 8, one first region 2020 in the first doping region 202 is near the channel region 201. As shown in FIG. 11, one first region 2020 in the first doping region 202 is near the first ohmic contact region 203. As shown in FIG. 15, two first regions 2020 in the first doping region 202 are provided. For example, one first region 2020 is near the channel region 201, with a width of D01 along the first direction, and the other first region 2020 is near the first ohmic contact region 203, with a width of D00 along the first direction, where D00+D01=½D1. As shown in FIG. 8, FIG. 11, and FIG. 15, the shielding layer 60 covers the first junction and/or the second junction. In another embodiment of the present disclosure, the shielding layer 60 does not cover the first junction and/or the second junction as shown in FIG. 3.

It is understood that in the present disclosure, the shielding layer 60 may overlap with the first doping region 202 in the direction perpendicular to the plane of the substrate 10. When the shielding layer 60 is connected to a fixed potential, it may stabilize the electric field intensity of the first region 2020. This may prevent avalanche multiplication of charge carriers in the first region 2020, prevent sudden changes in current in the first region 2020, and thus mitigate the kink effect effectively, i.e., mitigate the short-channel effect.

Based on experimental data, when high and low voltages are applied to the source 40 and the drain 50 of the transistor, the width of the first region 2020 may vary as D0=0, D0=½D1, and D0=D1, and the electric field intensity at various area in the semiconductor layer 20 is measured. When D0=0, the electric field intensity at the first junction 2021 may be very high and exhibit a peak of the electric field intensity. Moreover, the electric field intensity at the first junction 2021 when D0=0 is greater than the electric field intensity at the first junction 2021 when D0=½D1 and D0=D1. The electric field intensity in the first region 2020 may decrease gradually when D0=0. When D0=½D1, the electric field intensity in the first region 2020 may decrease first, increase in a peak and decrease again where the peak value may be close to the peak value at the first junction 2021. When D0=D1, the electric field intensity in the first region 2020 may show a significant decrease followed by a sharp increase in a peak where the peak value is much greater than the peak value at the first junction 2021. Therefore, considering the electric field intensity at various area, when D0=½D1, the peak value at the first junction 2021 may be smaller, and the electric field intensity in the first region 2020 may decrease first, increase in a peak and decrease again. This may indicate a relatively low quantity of charge carriers in the first region 2020, and achieve better performance in mitigating sudden changes in current and the short-channel effect.

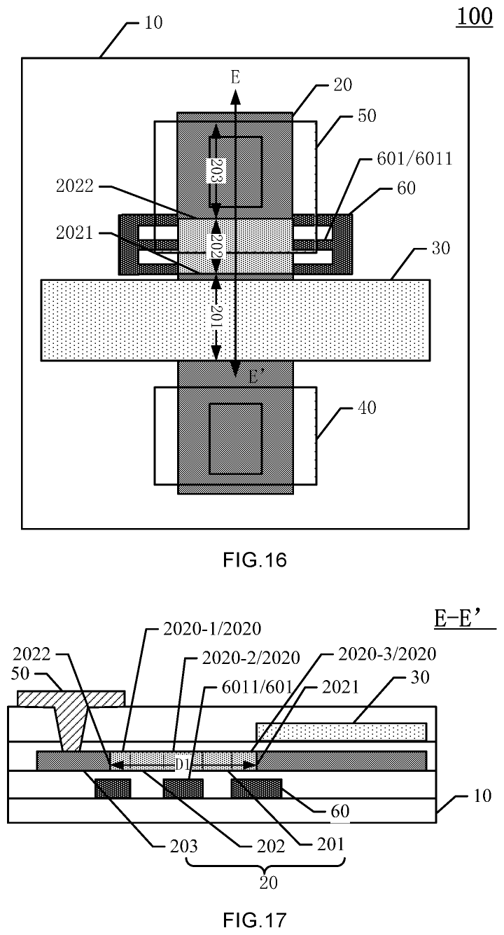

In some embodiments, referring to FIG. 15, FIG. 16, and FIG. 17. FIG. 16 illustrates a partial magnified view of a transistor in another exemplary array substrate according to various embodiments of the present disclosure. FIG. 17 illustrates a cross-sectional view along the E-E′ direction in FIG. 16. As shown in FIGS. 16 and 17, the shielding layer 60 includes a first portion 601. The first portion 601 is an area overlapping with the first doping region 202 in the direction perpendicular to the plane of the substrate 10. The first portion 601 includes a plurality of sub-portions 6011. Along the first direction, a sum of the widths of the sub-portions 6011 is D0.

As shown in FIG. 15, the first portion 601 includes two sub-portions 6011. For example, the two sub-portions 6011 overlap with the first junction 2021 and the second junction 2022 in the direction perpendicular to the plane of the substrate 10, respectively. As shown in FIG. 16 and FIG. 17, the first portion includes three sub-portions 6011. For example, in the direction perpendicular to the plane of the substrate 10, two of the three sub-portions overlap with the first junction 2021 and the second junction 2022, and another sub-portion 6011 overlaps with the middle portion of the first region 2020. Optionally, the first region 2020 may include three sub-portions. It is understood that the plurality of sub-portions may be connected and/or un-connected. The three sub-portions 6011 are connected as shown in FIG. 16, while the two sub-portions 6011 are un-connected as shown in FIG. 15.

Along the first direction, the sum of the widths of the sub-portions 6011 is equal to D0. It is understood that in the direction perpendicular to the plane of the substrate 10, the plurality of sub-portions 6011 overlapping with the first region 202 may stabilize the electric field intensity of the first region 2020 effectively. Therefore, the sum of the sub-portions may play a role in stabilizing and reducing the electric field intensity of the first region 2020. Optionally, the sum of the widths of the sub-portions 6011 D0 is equal to ½D1. The peak value at the first junction 2021 may be smaller. The electric field intensity in the first region 2020 may decrease first, increase in a peak and decrease again. This may indicate a relatively low quantity of charge carriers in the first region 2020, and achieve better performance in mitigating sudden changes in current and the short-channel effect.

In some embodiments, the plurality of sub-portions 6011 are connected as shown in FIG. 16. Therefore, one fixed potential may be connected to one of the plurality of sub-portions 601,1 and multiple fixed potentials may not be necessary. Additionally, in the manufacturing process, the shielding layer 60 may be fabricated first and then a portion may be removed by dry etching and/or other methods, leaving the remaining portion as the sub-portions 6011. This manufacturing method may be relatively simple.

In some embodiments, the plurality of sub-portions 6011 are not connected as shown in FIGS. 12 and 13. For example, the plurality of sub-portions 6011 are not connected as shown in FIG. 12 and may be fabricated individually during manufacturing. Optionally, at least one of the plurality of sub-portions 6011 may be connected to a different fixed potential.

In some embodiments, referring to FIG. 12, the plurality of sub-portions 6011 are connected to different fixed potentials.

It is understood that the number of accumulated charge carriers in the first doping region 202 may vary depending on the area. In this embodiment, the plurality of sub-portions 6011 may overlap with the first doping region 202, and the sub-portions 6011 may not connected. Thus, the plurality of sub-portions 6011 may be connected to different fixed potential based on the numbers of accumulated charge carriers. The sub-portion 6011 corresponding to an area with more accumulated charge carriers may be connected to a lower fixed potential, favoring the stable reduction of the electric field intensity at the area. The sub-portion 6011 corresponding to an area with fewer accumulated charge carriers may be connected to a slightly higher fixed potential, thereby saving energy consumption. As shown in FIG. 13, three sub-portions 6011 are illustrated schematically. The three sub-portions 6011 are not connected and may be connected to different fixed potentials. For example, the sub-portion 6011 over the side of the channel region 201 is connected to a slightly higher fixed potential because the number of the accumulated charge carriers over the side of the channel region 201 is less than the number of the accumulated charge carriers over the side of the first ohmic contact region 203. The sub-portion 6011 over the side of the first ohmic contact region 203 is connected to a slightly lower fixed potential.

In some embodiments, referring to FIGS. 6 to 8, the first junction 2021 is the junction between the first doping region 202 and the channel region 201. In the direction perpendicular to the plane of the substrate, the shielding layer 60 covers the first junction 2021. The first region 2020 in the first doping region 202 is over the side of the channel region 201.

It is understood that the shielding layer 60 also covers the first junction 2021 between the first doping region 202 and the channel region 201, and further cover the first region 2020 which extends from the first junction to the side of the first ohmic contact region 203. It should be noted that a sudden increase in resistance at the first junction 2021 may occur when charge carriers flow from the channel region 201 to the first doping region 202 of low doping concentration. This may form a barrier at the first junction 2021, making the area prone to charge carrier accumulation. The shielding layer 60 covering the first junction 2021 in the direction perpendicular to the plane of the substrate 10 may reduce the electric field intensity effectively at the first junction 2021. Additionally, the shielding layer 60 may cover half of the first doping region 202 in this embodiment. When the total width D0 of the first region 2020 along the first direction is equal to half the total width D1 of the first doping region 202, the peak value of the electric field intensity at the first junction 2021 is relatively low. The electric field intensity in the first region 2020 decreases first, increases in a peak, and then decreases again. This may result in fewer charge carriers in the first region 2020 and achieve the best performance in mitigating sudden changes in current and the short-channel effect.

It is understood that, due to the avalanche multiplication of charge carriers near the drain under high drain voltage, the drain current increases rapidly with drain voltage, leading to occurrence of the Kink effect. The avalanche multiplication of charge carriers near the drain may be more likely to occur. In this embodiment, the first ohmic contact region 203 is connected to the drain, and the shielding layer 60 covers the first junction 2021 in the direction perpendicular to the plane of the substrate. This may reduce the electric field intensity effectively at the first junction 2021 and lower the numbers of charge carriers in the first region 2020, thereby achieving the best performance in mitigating the current variation and improving the short-channel effect.

In some embodiments, referring to FIGS. 1 to 3, a length of the portion of the shielding layer 60 overlapping with the first doping region 202 may be greater than or equal to 0.5 μm and less than or equal to 1.5 μm in the direction from the channel region 201 to the first ohmic contact region 203.

The inventors found through experiments that, in the direction from the channel region 201 to the first ohmic contact region 203, if the length of the overlapping between the shielding layer and the first doing region 202 is too small, a high electric field intensity may occur at the first junction 2021. In the direction from the channel region 201 to the first ohmic contact region 203, if the length of the overlapping between the shielding layer and the first doing region 202 is too large, a sudden increase in electric field intensity may occur near the second junction 2022, and the peak value at the second junction 2022 may be much greater than the peak value at the first junction 2021. Therefore, in the direction from the channel region 201 to the first ohmic contact region 203, the length of the overlapping between the shielding layer and the first doing region 202 may be neither too large nor too small. In this embodiment, in the direction from the channel region 201 to the first ohmic contact region 203, the length of the overlapping between the shielding layer and the first doing region 202 may be greater than or equal to 0.5 μm and less than or equal to 1.5 μm. This may ensure that the peak value of the electric field intensity at the first junction 2021 is not too large and prevent a sudden increase in electric field intensity at the second junction 2022. This configuration may result in a relatively low quantity of charge carriers in the first doping region 202, thereby achieving good performance in mitigating sudden changes in current and the short-channel effect.

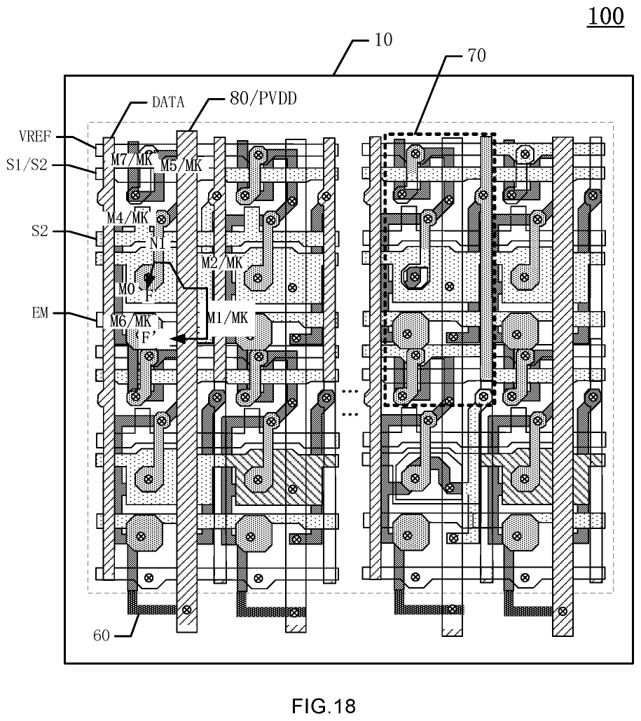

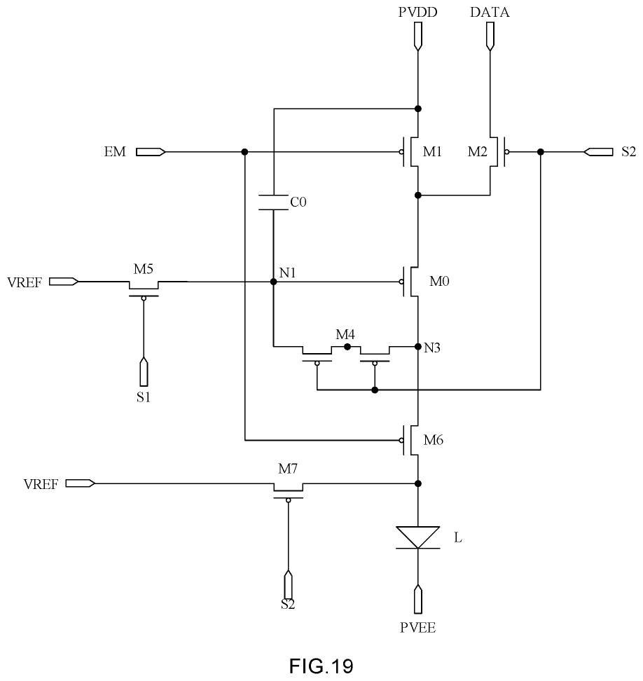

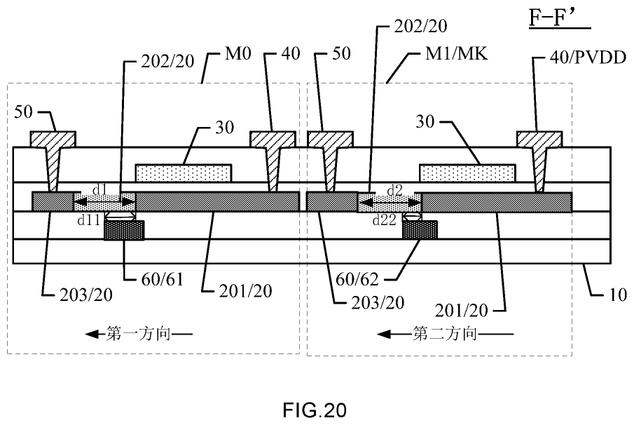

In some embodiments, referring to FIG. 18, FIG. 19, and FIG. 20. FIG. 18 illustrates a planar structural schematic diagram of another exemplary array substrate according to various embodiments of the present disclosure. FIG. 19 illustrates a pixel circuit diagram provided by the present disclosure. FIG. 20 illustrates a sectional view along the F-F′ direction in FIG. 18. In FIG. 18, only eight pixel circuits 70 are shown for illustrative purposes. It is understood that the array substrate 100 may include the plurality of pixel circuits 70. The equivalent circuit of the pixel circuit 70 in FIG. 18 can be referred to FIG. 19. The array substrate 100 may include a plurality of driving transistors M0 and a plurality of switch transistors MK. A first direction is the direction from the channel region 201 of the driving transistor M0 to the first ohmic contact region 203. Along the first direction, a length of the first doping region 202 of the driving transistor M0 is d1, and a length of overlap between the shielding layer 60 and the first doping region 202 of the driving transistor M0 is d11. A second direction is the direction from the channel region 201 of the driving transistor M0 to the first ohmic contact region 203. Along the second direction, a length of the first doping region 202 of the switch transistor MK is d2, and a length of overlap between the shielding layer 60 and the first doping region 202 of the switching transistor MK is d22, where |d11−½×d1|/d1<|d22−½×d2|/d2.

Specifically, the pixel circuit 70 may include the plurality of driving transistors M0 and the plurality of switch transistors MK. The driving transistor M0 may be a high-current transistor. The pixel circuit 70 may include a first switch transistor M1, a second switch transistor M2, a driving transistor M0, a fourth switch transistor M4, a fifth switch transistor M5, a sixth switch transistor M6, a seventh switch transistor M7, a storage capacitor Cst, and a light-emitting element L. The first switch transistor M1, the second switch transistor M2, the fourth switch transistor M4, the fifth switch transistor M5, the sixth switch transistor M6, and the seventh switch transistor M7 are all switch transistors MK. In the present disclosure, the example of the pixel circuit 70 as a 7T1C is used for illustrative purposes. Specifically, a control terminal of the first switch transistor M1 is electrically connected to a light-emitting signal input terminal EM, a first terminal of the first switch transistor M1 is electrically connected to a first power signal terminal PVDD, and a second terminal of the first switch transistor M1 is electrically connected to a first terminal of the driving transistor M0. A control terminal of the second switch transistor M2 is electrically connected to a second scan signal input terminal S2, a first terminal of the second switch transistor M2 is electrically connected to a data signal input terminal DATA, and a second terminal of the second switch transistor M2 is electrically connected to the first terminal of the driving transistor M0. A control terminal of the driving transistor M0 is electrically connected to a second terminal of the fifth switch transistor M5, the first terminal of the driving transistor M0 is electrically connected to a second terminal of the first switch transistor M1 and the second terminal of the second switch transistor M2. A control terminal of the fourth switch transistor M4 is electrically connected to the second scan signal input terminal S2, a first terminal of the fourth switch transistor M4 is electrically connected to the second terminal of the fifth switch transistor M5 and a second terminal of the storage capacitor Cst, and a second terminal of the fourth switch transistor M4 is electrically connected to the second terminal of the driving transistor M0 and a first terminal of the sixth switch transistor M6. A control terminal of the fifth switch transistor M5 is electrically connected to a first scan signal input terminal S1, a first terminal of the fifth switch transistor M5 is electrically connected to a reference voltage signal input terminal VREF, and the second terminal of the fifth switch transistor M5 is electrically connected to the control terminal of the driving transistor M0. A control terminal of the sixth switch transistor M6 is electrically connected to the light-emitting signal input terminal EM, a first terminal of the sixth switch transistor M6 is electrically connected to the second terminal of the driving transistor M0 and the second terminal of the fourth switch transistor M4, and a second terminal of the sixth switch transistor M6 is electrically connected to an anode of the light-emitting element L. A control terminal of the seventh switch transistor M7 is electrically connected to the second scan signal input terminal S2, a first terminal of the seventh switch transistor M7 is electrically connected to the reference voltage signal input terminal VREF, and the second terminal of the seventh switch transistor M7 is electrically connected to a first terminal of the light-emitting element L. The first terminal of the light-emitting element L is electrically connected to the second terminal of the sixth switch transistor M6 and the second terminal of the seventh switch transistor M7, and a second terminal of the light-emitting element L is electrically connected to a second power signal terminal PVEE. A first terminal of the storage capacitor Cst is electrically connected to the first power signal terminal PVDD, and a second terminal of the storage capacitor Cst is electrically connected to the control terminal of the driving transistor M0, the first terminal of the fourth switch transistor M4, and the second terminal of the fifth switch transistor M5.

As shown in FIG. 18, the shielding layer 60 in a display area AA is covered by other film layers, and a portion of exposed shielding layer 60 is shown in a non-display area BB. The sectional view of the driving transistor M0 and the first switch transistor M1 is shown in FIG. 20 as an example for illustrative purposes, where a drain 50 of the first switch transistor M1 is also a source 40 of the driving transistor M0. It is understood that a length of semiconductor layer 20 in the driving transistor M0 may not be equal to a length of semiconductor layer 20 in the switch transistor MK. Here, it is only illustratively explained.

The driving transistor M0 may be a high-current transistor where the voltage applied to the driving transistor M0 is higher than the voltage applied to the switch transistor MK. Therefore, avalanche multiplication of charge carriers may be more likely to occur in the driving transistor M0. In this embodiment, along a first direction, a length of the first doping region 202 of the driving transistor M0 is d1, and a length of the overlap between the first doping region 202 of the driving transistor M0 and the shielding layer 60 is d11. The first direction is from the channel region 201 of the driving transistor M0 to the first ohmic contact region 203. Along a second direction, a length of the first doping region 202 of the switch transistor MK is d2, and a length of the overlap between the first doping region 202 of the switch transistor MK and the shielding layer 60 is d22. The second direction is from the channel region 201 of the driving transistor M0 to the first ohmic contact region 203. The condition |d11−½×d1/d1<|d22−½×d2|/d2 holds, where |d11−½×d1|/d1 represents the deviation between the length of the overlap between the first doping region 202 of the driving transistor M0 and the shielding layer 60 and half of the length of the first doping region 202, and |d22−½×d2|/d2 represents the deviation between the length of the overlap between the first doping region 202 of the switch transistor MK and the shielding layer 60 and half of the length of the first doping region 202.

As disclosed above, when the length of the overlap between the first doping region 202 and the shielding layer 60 is half of the length of the first doping region 202, the peak value at the first junction 2021 may be smaller, and the electric field intensity in the first region 2020 may decrease first, increase in a peak and decrease again. The number of charge carriers in the first region 2020 may be relatively low, achieving the best performance in mitigating sudden changes in current. Since the driving transistor M0 is a high-current transistor, if the driving transistor M0 experiences a short-channel effect, it will significantly affect the electrical performance of the pixel circuit 70. In this embodiment, comparing to the switch transistor MK, |d11−½×d1|/d1<|d22−½×d2|/d2, indicating that the length of the overlap between the first doping region 202 of the driving transistor M0 and the shielding layer 60 is closer to half of the length of the first doping region 202. This may mitigate the short-channel effect of the driving transistor M0 effectively, thereby improving the electrical performance of the pixel circuit 70.

In some embodiments, referring to FIG. 19 and FIG. 20, the array substrate 100 includes a plurality of driving transistors M0 and a plurality of switch transistors MK. The shielding layer 60 includes a first shielding layer 61 and a second shielding layer 62. For example, the first shielding layer 61 overlaps at least partially with the first doping region 202 of the driving transistor M0 in the direction perpendicular to the plane of the substrate 10, the second shielding layer 62 overlaps at least partially with the first doping region 202 of the switch transistor MK in the direction perpendicular to the plane of the substrate 10, and a fixed potential connected to the first shielding layer 61 is different from a fixed potential connected to the second shielding layer 62.

It is understood that a first fixed potential V1 connected to the shielding layer 60 corresponding to the driving transistor M0 may not be equal to the second fixed potential V2 connected to the shielding layer 60 corresponding to the switch transistor MK. As shown in FIG. 20, the driving transistor M0 is a high-current transistor where the voltage applied to the driving transistor M0 is higher than the voltage applied to the switching transistor MK. Therefore, the driving transistor M0 may be more prone to the issue of avalanche multiplication of charge carriers. In this case, the first fixed potential V1 connected to the first shielding layer 61 corresponding to the driving transistor M0 may be lower than the second fixed potential V2 connected to the second shielding layer 62 corresponding to the switch transistor. This may allow for a better stabilization of the electric field intensity in the first doping region 202 of the driving transistor M0 when a higher voltage is applied, improving the electrical performance of the pixel circuit 70 effectively.

In some embodiments, different fixed potentials may be connected to different driving transistors M0. For example, in different pixel circuits 70, the voltage applied to the drive transistor M0 are different, meaning that the drive transistor M0 may be turned on to different degree and the corresponding amount of generated charge carriers may differ. In this case, the overlapping shielding layers 60 corresponding to different drive transistors M0 may be connected to different fixed potentials.

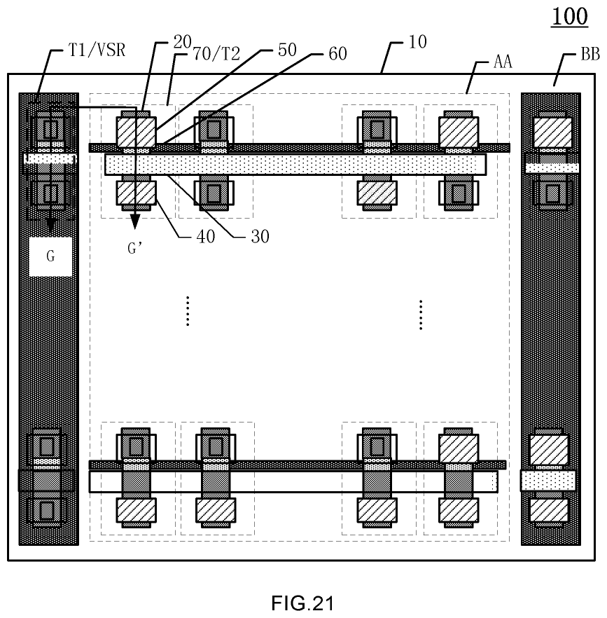

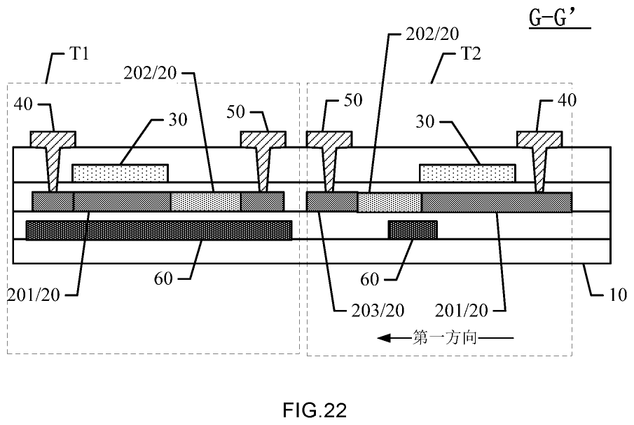

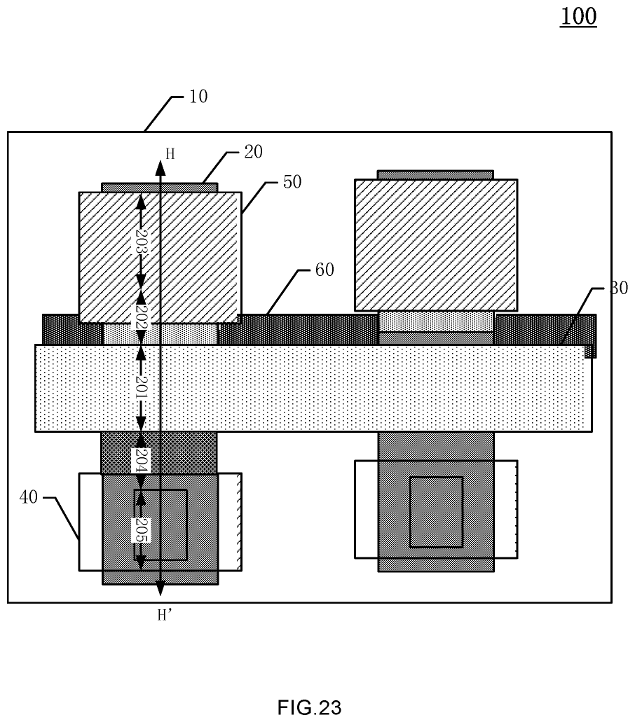

In some embodiments, referring to FIGS. 21 and 22, FIG. 21 illustrates a planar structural schematic diagram of another exemplary array substrate according to various embodiments of the present disclosure. FIG. 22 illustrates a cross-sectional view along the G-G′ direction in FIG. 21. As shown in FIG. 21, the array substrate 100 include a display area AA and a non-display area BB surrounding the display area AA. The non-display area BB includes a plurality of shift registers VSR. The shift register VSR includes a plurality of first transistor T1. The display area AA includes a plurality of pixel circuits 70. The pixel circuit 70 includes a plurality of second transistors T2. For example, a projection of the first doping region 202 of the first transistor T1 in the plane of the substrate 10 is within a projection of the shielding layer 60 in the plane of the substrate 10. In the second transistor T2, a ratio of the length of the overlap between the first doping region 202 and the shielding layer 60 along a first direction to the length of the first doping region 202 along the first direction is ½. The first direction is the direction from the channel region 201 to the first ohmic contact region 203.

Specifically, the non-display area BB may be arranged around the display area AA or semi-surrounding the display area AA, and the present disclosure is not limited thereto. The non-display area BB may include a plurality of cascaded shift registers VSR. The plurality of cascaded shift registers VSR may be arranged as a single-side border or a double-side border. As shown in FIG. 21, an example of shift registers VSR as a double-side border is illustrated. The shift register VSR may include the plurality of first transistors T1. As shown in FIG. 21, one first transistor T1 is exemplified for illustrative purposes.

It should be noted that the shielding layer 60 corresponding to the first transistor T1 and the shielding layer 60 corresponding to the second transistor T2 may not be connected. In this case, different fixed potentials may be connected.

It is understood that the first transistor T1 in the shift register VSR serves only as a switch and does not need to drive the display because the non-display area BB is not used for display purposes. Typically, the voltage applied to the first transistor T1 may not be very high. Therefore, the area of the shielding layer 60 may be set larger. The projection of the first doping region 202 of the first transistor T1 on the plane of the substrate 10 is within the projection of the shielding layer 60 on the plane of the substrate 10. Alternatively, the shielding layer 60 may cover the entire non-display area BB, facilitating fabrication without the need for local etching of the shielding layer 60 in the non-display area BB. In the display area AA, the second transistor T2 functions as a driving transistor M0. Typically, the input voltage to the driving transistor M0 may be relatively high, and a higher voltage may be more prone to cause short-channel effect. Therefore, in the display area AA, the ratio of the length of the overlap between the first doping region 202 and the shielding layer 60 along the first direction to the length of the first doping region 202 in the first direction may not be too large. As disclosed above, when this ratio is ½, the mitigation in short-channel effects may be optimal.

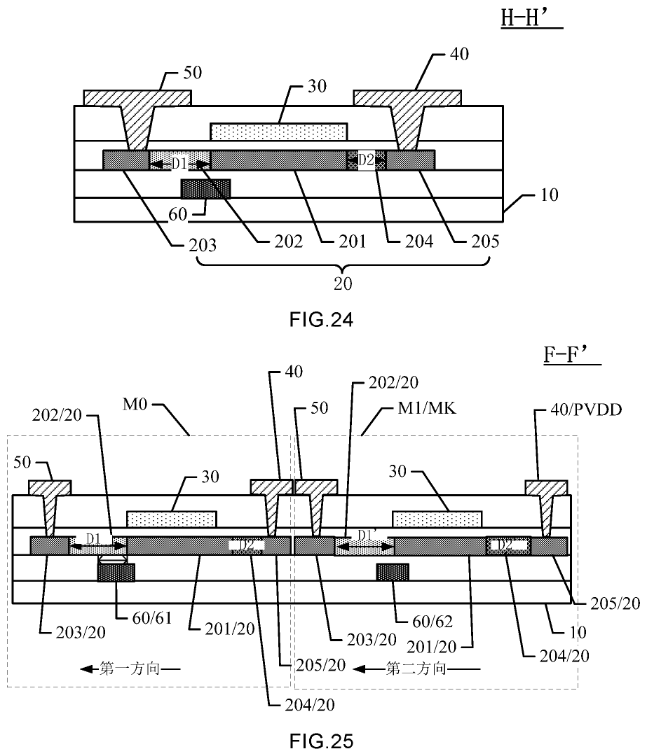

In some embodiments, referring to FIG. 23 and FIG. 24, FIG. 23 illustrates a planar structural schematic diagram of another exemplary array substrate according to various embodiments of the present disclosure, and FIG. 23 shows only two transistors of the array substrate 100 for illustrative purposes. FIG. 24 illustrates a cross-sectional view along the H-H′ direction in FIG. 23. For example, the semiconductor layer 20 further includes a second doping region 204 and a second ohmic contact region 205 over the side of the channel away from the first doping region 202, where the second ohmic contact region 205 is electrically connected to the source 40.

It is understood that the first ohmic contact region 203 may be the contact region of the drain 50, the second ohmic contact region 205 may be the contact region of the source 40, the first doping region 202 may have a low doping concentration, and the doping concentration of the second doping region 204 may be higher than the doping concentration of the first doping region 202. A slightly higher doping concentration in the second doping region 204 over the side of the source 40 may ensure that sufficient charge carriers are generated over the side of the source 40. This may allow the semiconductor layer 20 to exhibit conductor characteristics after the potential is connected to the gate 30, thereby ensuring that the current flows from the source 40 to the drain 50.

In some embodiments, referring to FIG. 24, the ratio of the doping concentration of the first doping region 202 to the doping concentration of the second doping region 204 may be between 1/20 and ⅕. The doping concentration of the second doping region 204 may need to be sufficiently high to ensure the generation of sufficient charge carriers over the side of the source 40, allowing the semiconductor layer 20 to exhibit conductor characteristics after the potential is connected to the gate 30, thereby ensuring that current flows from the source 40 to the drain 50. The doping concentration of the first doping region 202 may need to be sufficiently low to further mitigate the short-channel effect.

In some embodiments, referring to FIG. 24, along a direction from the channel region 201 to the first ohmic contact region 203, a length of the first doping region 202 is D1. Along a direction from the second ohmic contact region 205 to the channel region 201, a length of the second doping region 204 is D2, where D1>D2.

It is understood that the second doping region 204 is in the semiconductor layer 20 over the side of the source 40 and the first doping region 202 is in the semiconductor layer 20 over the side of the drain 50. The second doping region 204 is highly doped to generate sufficient charge carriers, allowing the semiconductor layer 20 to exhibit conductor characteristics after the potential is connected to the gate 30. However, the length of the second doped region 204 may not need to be excessively long. If it is too long, an excess of charge carriers may accumulate in the first doping region 202, leading to avalanche multiplication of charge carriers when a high input voltage is applied. In this embodiment, D1>D2 may ensure that the length of the second doping region 204 is not excessively long and thus a moderate number of charge carriers are generated. This may ensure the characteristics of the semiconductor layer 20 while preventing an excessive accumulation of charge carriers in the first doping region 202.

FIG. 25 illustrate another cross-sectional view along the F-F′ direction in FIG. 18. Referring to FIG. 25, the array substrate 100 includes a driving transistor M0 and a switch transistor MK. In the switching transistor MK, a difference in length between the first doping region 202 and the second doping region 204 is W1. In the driving transistor M0, a difference in length between the first doping region 202 and the second doping region 204 is W2. Specifically, W2>W1.

In this embodiment, the difference in length between the first doping region 202 D1 and the second doping region 204 D2 in the driving transistor M0 is W2. The difference in length between the first doping region 202 D1′ and the second doping region 204 D2′ in the switch transistor MK is W1. Since the driving transistor M0 typically experiences higher input voltage, generating more charge carriers, the length of the second doping region 204 may not be excessively large. W2 the difference in length between the first doping region 202 and the second doping region 204 may need to be relatively large. This may ensure that the driving transistor M0 exhibits a mitigated short-channel effect when subjected to a high input voltage. Typically, the switch transistor MK may operate at a lower input voltage with fewer generated charge carriers. W1 the difference in length between the first doping region 202 and the second doping region 204 may be relatively small, making it easier to manufacture when the lengths of the first doping region and the second doping region are similar.

In some embodiments, referring to FIG. 18, the array substrate 100 further includes a plurality of first signal lines 80. For example, the first signal line 80 is in the same layer as the source 40 and drain 50, and electrically connected to the shielding layers 60.

As shown in FIG. 18, the array substrate 100 further includes the plurality of first signal lines 80. For example, the first signal line 80 is in the same metal layer as the source 40 and the drain 50, and the first signal line 80 is electrically connected to the shielding layer 60 through via holes. By electrically connecting the first signal line 80 to the shielding layer 60, a fixed potential is connected to the first signal line 80. This may stabilize the electric field intensity in the first doping region 202 and mitigate the short-channel effect.

In some embodiments, referring to FIG. 18, the array substrate 100 may include a plurality of power supply voltage signal lines. The power supply voltage signal lines may be reused as the first signal lines 80. That is, the voltage of the power supply voltage signal lines may be applied to the shielding layers 60 through via holes, eliminating the need for separate first signal lines 80.

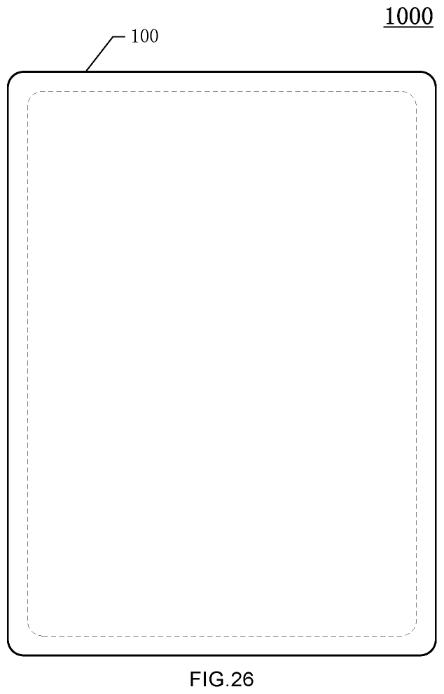

This embodiment also provides a display panel. The display panel includes the array substrate as disclosed above. FIG. 26 illustrates a schematic plan view of an exemplary display panel provided by the present disclosure. As shown in FIG. 26, the display panel 1000 includes the array substrate 100, where the array substrate is the array substrate 100 provided in any of the embodiments of the present disclosure. The display panel of the present disclosure may be an organic light-emitting display panel, not shown in the figure. Specifically, the organic light-emitting display panel may include a plurality of anodes, a plurality of cathodes, and a plurality of hole transport layers, a plurality of organic light-emitting layers, as well as a plurality of electron transport layers, all set between the anodes and the cathodes. The anode provides hole injection, and the cathode provides electron injection. Under external voltage, holes and electrons injected by the cathode and anode, respectively, recombine in the organic light-emitting layer to form bound electron-hole pairs (i.e., excitons). Excitons radiate and emit photons, producing visible light. The embodiment in FIG. 26 uses a mobile phone as an example to illustrate the display panel 1000. It is understood that the display panel provided in the embodiments of the present disclosure is a display panel for display functions such as computer, TV, or in-car display panel, and the present disclosure is not specifically limited thereto. The display panel provided in the embodiments of the present disclosure has beneficial effects of the array substrate provided in the embodiments of the present disclosure. Specific details can be referred to the specific descriptions of the array substrate in the above embodiments, and are not repeated here in this embodiment.

Compared to the prior art, the array substrate and the display panel provided by the present disclosure offer at least the following advantageous effects.

In related technologies, reducing the size of transistors to mitigate short-channel effects may lead to a decrease in the effective channel length. When the effective channel length is reduced to the order of a dozen nanometers or even a few nanometers, the short-channel effect occurs. It primarily includes a decrease in threshold voltage with decreasing channel length (threshold voltage drift), a drain-induced reduction in the barrier potential (kink effect), and thermal electron effect. For long-channel semiconductor devices, the channel acts as a resistance. When the gate voltage is within a certain range, the semiconductor exhibits normal semiconductor characteristics with a constant input current. However, in the case of a short channel, as the voltage increases, threshold voltage drift becomes more severe, and the depletion region between the drain and the source becomes closer, causing current to flow from the drain to the source. This may lead to a decrease in the barrier potential height at the source, an increase in the drain current, and drain-induced barrier lowering (DIBL) effects. Additionally, at high drain voltage levels, avalanche multiplication of charge carriers occurs near the drain, causing a rapid increase in the drain current, leading to the kink effect. Moreover, thermal effect occurs under increasing voltage, leading to impact-induced electrons and sudden changes in current. The array substrate of the present disclosure includes a substrate, semiconductors over one side of the substrate, gates over the side of the semiconductors away from the substrate, sources, and drains over the side of the gates away from the substrate. The semiconductor includes a channel region, a first doping region, and a first ohmic contact region sequentially connected with the channel region and the first doping region. Shielding layers are between the substrate and the semiconductors. The shielding layers are connected to fixed potentials, and overlap at least partially with the first doping regions in the direction perpendicular to the plane of the substrate. On the one hand, low concentration doping is performed in the first doping region 202. After applying a voltage to the transistor, the low doping concentration in the first doping region leads to a decrease in the number of charge carriers when current flows from the channel region to the first ohmic contact region, thus addressing the issue of avalanche multiplication of charge carriers. At the same time, after a voltage is applied to the transistor, a trend of avalanche multiplication of charge carriers in the first doping region occurs when current flows from the channel region to the first ohmic contact region. However, in the present disclosure, the projection of the shielding layers on the plane of the substrate overlaps partially with the projection of the first doping regions on the plane of the substrate, and a capacitive coupling structure is formed between the shielding layer and the first doping region. Since the shielding layer is also connected to the fixed potential, the electric field intensity in the region where the first doping region overlap with the shielding layer in the direction perpendicular to the substrate is reduced following capacitive coupling principles. This prevents avalanche multiplication of charge carriers, mitigates thermal effect, prevents sudden changes in current and mitigate the kink effect, thereby addressing the short-channel effect.

It is not necessary for any item of the present disclosure to achieve all of the aforementioned technical effects simultaneously. A detailed description of exemplary embodiments of the present disclosure is provided in reference to the accompanying drawings, which will clarify other features and advantages of the disclosure.

What is claimed is:

1. An array substrate, comprising
a substrate,
a semiconductor layer over the substrate,
a gate over a side of the semiconductor layer away from the substrate, and
a source and a drain on sides of the gate, wherein the semiconductor layer comprises a channel region, a first doping region, and a first ohmic contact region, which are sequentially connected; and
a shielding layer between the substrate and the semiconductor layer, wherein the shielding layer is connected to a fixed potential, and the shielding layer at least partially overlaps with the first doping region in a direction perpendicular to a plane of the substrate.

2. The array substrate according to claim 1, wherein a first junction is a junction of the first doping region and the channel region, a second junction is a junction of the first doping region and the first ohmic contact region, and the shielding layer cover the first junction and/or second junction in the direction perpendicular to the plane of the substrate.

3. The array substrate according to claim 1, wherein the first doping region comprises a first region, the first region overlapping with the shielding layer in the direction perpendicular to the plane of the substrate; and
along a first direction, a total width of the first region is D0, a total width of the first doping region is D1, D0=½D1, and the first direction is from the channel region to the first ohmic contact region.

4. The array substrate according to claim 3, wherein the shielding layer comprises a first portion, the first portion overlapping with the first doping region in the direction perpendicular to the plane of the substrate; and
the first portion comprises a plurality of sub-portions, and along the first direction, a sum of the widths of the sub-portions is D0.

5. The array substrate according to claim 4, wherein the plurality of sub-portions are connected with each other.

6. The array substrate according to claim 4, wherein the plurality of sub-portions are unconnected with each other.

7. The array substrate according to claim 6, wherein the plurality of sub-portions are connected to different fixed potentials.

8. The array substrate according to claim 3, wherein the first junction is a junction of the first doping region and the channel region, the shielding layer covers the first junction in the direction perpendicular to the plane of the substrate, and the first region in the first doping region is over a side of the channel region.

9. The array substrate according to claim 1, wherein a length of the overlap between the shielding layer and the first doping region in a direction from the channel region to the first ohmic contact region is greater than or equal to 0.5 μm and less than or equal to 1.5 μm.

10. The array substrate according to claim 1, wherein the array substrate comprises a plurality of driving transistors and a plurality of switch transistors; and
along a first direction, a length of the first doping region of the driving transistor is d1, a length of the overlap between the first doping region and the shielding layer is d11, the first direction is from the channel region to the first ohmic contact region; and
along a second direction, a length of the first doping region of the switch transistor is d2, a length of the overlap between the first doping region and the shielding layer is d22, the second direction is from the channel region to the first ohmic contact region; and
$$\vert d 11 - 1 / 2 \times d 1 \vert / d 1 < \vert d 22 - 1 / 2 \times d 2 \vert / d 2.$$

11. The array substrate according to claim 1, wherein the array substrate comprises the plurality of driving transistors and the plurality of switch transistors; and
the shielding layer comprises a first shielding layer and a second shielding layer, the first shielding layer at least partially overlaps with the first doping region of the driving transistor in the direction perpendicular to the plane of the substrate, the second shielding layer at least partially overlaps with the first doping region of the switch transistor in the direction perpendicular to the plane of the substrate, and a fixed potential connected to the first shielding layer is different from a fixed potential connected to the second shielding layer.

12. The array substrate according to claim 1, wherein the array substrate comprises a display region and a non-display region surrounding the display region; and
the non-display region comprises a plurality of shift registers, the shift register comprises a first transistor, the display region comprises a plurality of pixel circuits, the pixel circuit comprises a second transistor, a projection of the first doping region of the first transistor in the shift register on the plane of the substrate is within a projection of the shielding layer on the plane of the substrate; and
along a first direction, a length of the overlap between the first doping region in the second transistor and the shielding layer is half of the length of the first doping region in the second transistor, and the first direction is from the channel region to the first ohmic contact region.

13. The array substrate according to claim 1, wherein the first ohmic contact region is electrically connected to the drain.

14. The array substrate according to claim 1, wherein the semiconductor layer further comprises a second doping region and a second ohmic contact region over a side of the channel away from the first doping region, and the second ohmic contact region is electrically connected to the source.

15. The array substrate according to claim 14, wherein along the direction from the channel region to the first ohmic contact region, a length of the first doping region is D1, and along the direction from the second ohmic contact region to the channel region, a length of the second doping region is D2, wherein D1>D2.

16. The array substrate according to claim 14, wherein the array substrate comprises the plurality of driving transistors and the plurality of switch transistors; and
in the switch transistor, the difference in length between the first doping region and the second doping region is W1; and
in the driving transistor, the difference in length between the first doping region and the second doping region is W2; and
wherein W2>W1.

17. The array substrate according to claim 14, wherein a ratio of a doping concentration of the first doping region to a doping concentration of the second doping region is between 1/20 and ⅕.

18. The array substrate according to claim 1, wherein the array substrate comprises a plurality of first signal lines, the first signal line is on the same layer as the source and the drain, and the first signal line is electrically connected to the shielding layer.

19. A display panel comprising:
an array substrate, comprising:
a substrate,
a semiconductor layer over the substrate,
a gate over a side of the semiconductor layer away from the substrate, and
a source and a drain on sides of the gate, wherein the semiconductor layer comprises a channel region, a first doping region, and a first ohmic contact region, which are sequentially connected; and
a shielding layer between the substrate and the semiconductor layer, wherein the shielding layer is connected to a fixed potential, and the shielding layer at least partially overlaps with the first doping region in a direction perpendicular to a plane of the substrate.

20. The display panel according to claim 19, wherein a first junction is a junction of the first doping region and the channel region, a second junction is a junction of the first doping region and the first ohmic contact region, and the shielding layer cover the first junction and/or second junction in the direction perpendicular to the plane of the substrate.
